(19) United States
(12) Patent Application Publication
(10) Pub. No.: US 2010/0177912 A1
(43) Pub. Date: Jul. 15, 2010

(54) System and Method for Providing Volume Control

(75) Inventor: Christopher Walsh, San Diego, CA (US)

Correspondence Address: CROWELL & MORING LLP;INTELLECTUAL PROPERTY GROUP, P.O. BOX 14300, WASHINGTON, DC, 20044-4300, US

(73) Assignees: SONY CORPORATION, Tokyo (JP); SONY ELECTRONICS INC., Park Ridge, NJ (US)

(21) Appl. No.: 12/351,694

(22) Filed: Jan. 9, 2009

(51) Int. Cl. H03G 3/00

(52) U.S. Cl. 381/107

(57) ABSTRACT

User volume control when switching from one external input port to another is provided. Once a user request to switch from one input port to another is received by an electronic user device, a determination may be made as to whether there is a stored user-defined default volume level that corresponds to the user requested or selected input port. If so, this previously-stored user-defined default volume level may be retrieved from memory and used to adjust the current volume setting of the electronic user device. Once the volume level has been adjusted in accordance with the user-defined default information, the user electronic device may then switch to the requested input port in accordance with the user's request.

### FIELD OF THE INVENTION

The present invention relates in general to a system and method for providing volume control, and more particularly to enabling input-specific volume control.

### BACKGROUND

Most televisions and similar user electronic devices today have multiple inputs to accommodate the many different types of content sources. One such typical user electronic device 105 (e.g., television) is depicted in FIG. 1, and includes processing logic 115, an input interface 120, a display 125 and one or more speakers 130. The electronic user device 105 may also communicate with a user input device 110, which can be a stand alone unit or integrated with user electronic device 105. For example, the user input device 110 may be a remote control device used to select an external input port from which to receive media content. The user input device 110 may include one or more buttons integrated with the user electronic device 105 to provide such external input port selection. In addition, a typical user electronic device 105 will also have some form of onboard nonvolatile memory, such as memory 135, for storing various user settings. Such memory 135 may also be electrically connected to the processing logic 115, as shown in FIG. 1.

Referring now to FIG. 2, system 200 illustrates a diagram of a typical input interface 205 (e.g., input interface 120 of FIG. 1) of an electronic user device (e.g., television) usable in conjunction with the invention. In particular, input interface 205 includes certain switching circuitry 210 for selection between one of a plurality of possible input sources. The input interface 205 includes a plurality of input ports, such as IEEE-1394 ports 225, composite ports 230, component video ports 235, S-video port 240 and HDMI ports 245, etc. for connection to external media content devices. Controller 220 provides, in part, selection signals to switching circuitry 210 and may be integrated with a main processor of the electronic user device (e.g., processing logic 115). When an input source is selected, switching circuitry 210 provides the selected output source to output 215 (e.g., display 125, speakers 130, etc.).

Referring now to FIG. 3, depicted is an exemplary external view of a typical input interface 305 (e.g., input interface 120) of an electronic user device usable in connection with the invention. Input interface 305 may be integrated with a user electronic device such as a television or intermediate device for a display unit. The input interface 305 can include IEEE-1394 ports 325a-b, composite ports 330a-f, component video ports 335a-f, audio ports 340a-d, HDMI ports 345a-b, S-video ports 350a-b and a coaxial port 355 for connection to external devices.

Currently, many user electronic devices, such as televisions, will produce different sound levels at a given volume setting based on the type of external input port being used to receive the media content in question. For example, in order to produce the same amount of sound (i.e., same decibel level), audio content received through a “PC Input” port will require a much higher volume setting than would audio content received through a High-Definition Multimedia Interface (HDMI) port. This can also be due to the fact that different audio source devices can output volumes at different decibel levels.

The result of the above deficiency is that, when a user switches from one input (e.g., the PC Input) to another input (e.g., HDMI) without first adjusting the volume, the resulting sound level may be too low to hear, or worse yet so loud that it's uncomfortable to the user and/or a disturbance to others.

Additionally, there are some types of media content that users typically listen to at a higher volume than other content. For example, users tend to listen to music at a louder level than television programming. However, there is no current means to account for this, other than for the user to manually adjust the volume. Accordingly, there is a need in the art for a system and method of providing input-specific volume control which overcomes the aforementioned drawbacks.

### BRIEF SUMMARY OF THE INVENTION

Disclosed and claimed herein are systems and method for providing volume control. In one embodiment of the invention, a method for providing volume control for an electronic user device includes receiving a user request to switch an active external input port of the electronic user device to a new external input port, and determining if a user-defined default volume level is available for the new external input port. If so, the method includes retrieving the user-defined default volume level corresponding to the new external input port, adjusting a current volume setting based on the retrieved user-defined default volume level, and switching the active external input port to the new external input port.

Other aspects, features, and techniques of the invention will be apparent to one skilled in the relevant art in view of the following detailed description of the invention.

### BRIEF DESCRIPTION OF THE DRAWINGS

FIG. 1 depicts a typical electronic user device capable of being used in connection with the principles of the invention;

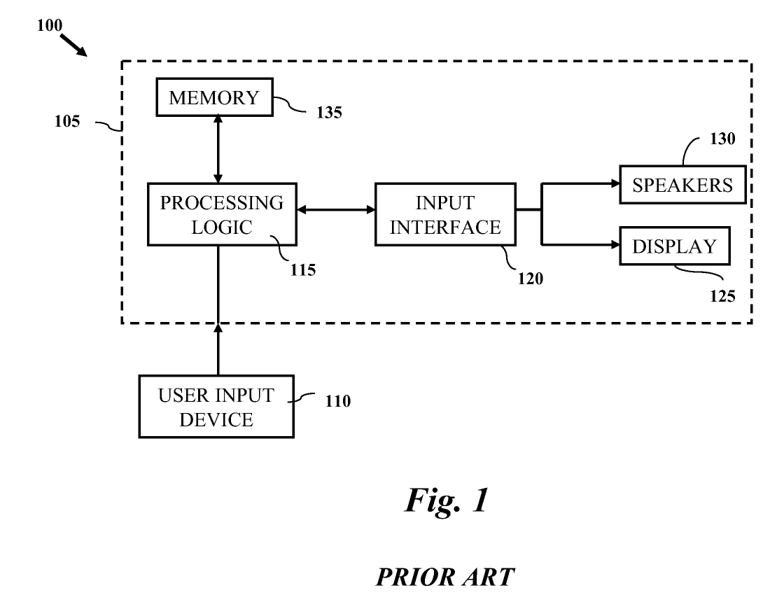

FIG. 2 depicts a schematic of a typical input interface of the electronic user device of FIG. 1 that is capable of receiving content from various media content sources;

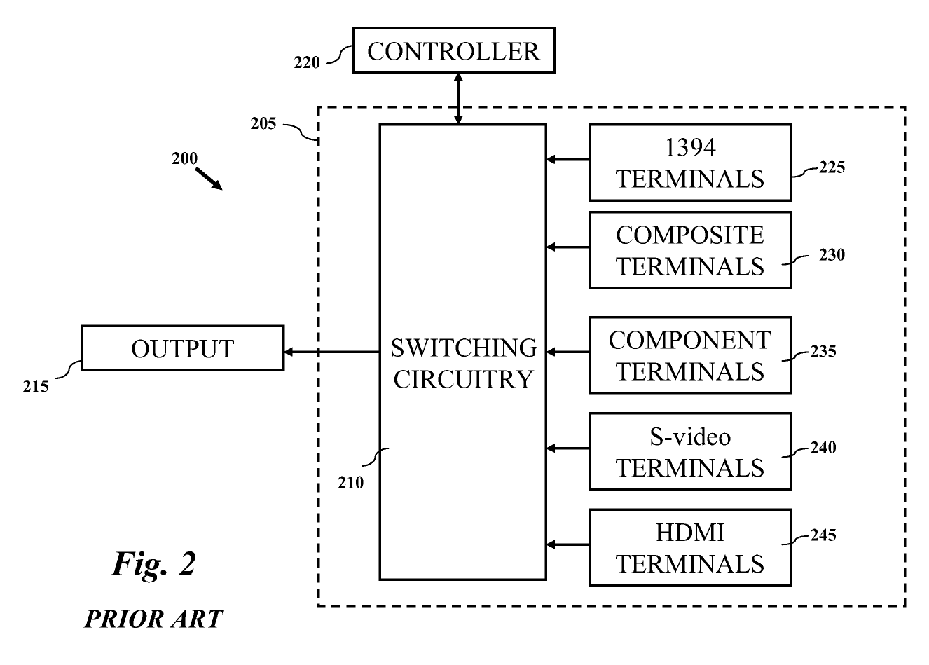

FIG. 3 depicts an external view of the input interface of FIG. 2;

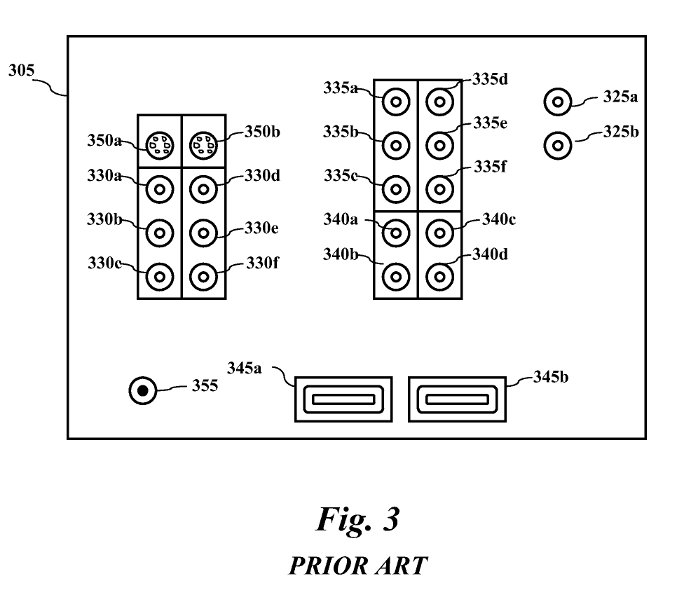

FIG. 4 depicts one embodiment of a process for carrying out one or more aspects of the invention; and

FIG. 5 depicts another embodiment of a process for carrying out one or more aspects of the invention.

### DETAILED DESCRIPTION OF EXEMPLARY EMBODIMENTS

The present disclosure relates to providing user volume control when switching from one external input port to another. To that end, in one embodiment a user request to switch from one input port to another is first received by an electronic user device. A determination may then be made as to whether there is a stored user-defined default volume level that corresponds to the user requested or selected input port. If so, the previously-stored user-defined default volume level corresponding to the selected port may be retrieved from memory and used to adjust the current volume setting of the electronic user device. In one embodiment, this adjustment operation may involve comparing a current volume setting to the retrieved volume level and determining if the current volume setting needs to be raised, lowered or left the same.

Once the volume level has been adjusted, the user electronic device may then switch to the requested input port in accordance with the user's request. Alternatively, the volume adjustment operation may occur before the port switching operation, or simultaneously therewith.

In this fashion, one aspect of the invention is to enable users to switch between external input ports (and hence media content sources), but not experience the volume level increases and decreases that currently exist when switching from certain input types to other input types.

Another aspect of the invention is to enable users to customize the volume level for their various media sources, such as having a higher volume level for music when switching the input port connected to a music source (e.g., DM input port), or a lower volume level when switching to the input port connected to standard television broadcast content.

As used herein, the terms “a” or “an” shall mean one or more than one. The term “plurality” shall mean two or more than two. The term “another” is defined as a second or more. The terms “including” and/or “having” are open ended (e.g., comprising). The term “or” as used herein is to be interpreted as inclusive or meaning any one or any combination. Therefore, “A, B or C” means “any of the following: A; B; C; A and B; A and C; B and C; A, B and C”. An exception to this definition will occur only when a combination of elements, functions, steps or acts are in some way inherently mutually exclusive.

Reference throughout this document to “one embodiment”, “certain embodiments”, “an embodiment” or similar term means that a particular feature, structure, or characteristic described in connection with the embodiment is included in at least one embodiment of the present invention. Thus, the appearances of such phrases or in various places throughout this specification are not necessarily all referring to the same embodiment. Furthermore, the particular features, structures, or characteristics may be combined in any suitable manner on one or more embodiments without limitation.

In accordance with the practices of persons skilled in the art of computer programming, the invention is described below with reference to operations that are performed by a computer system or a like electronic system. Such operations are sometimes referred to as being computer-executed. It will be appreciated that operations that are symbolically represented include the manipulation by a processor, such as a central processing unit, of electrical signals representing data bits and the maintenance of data bits at memory locations, such as in system memory, as well as other processing of signals. The memory locations where data bits are maintained are physical locations that have particular electrical, magnetic, optical, or organic properties corresponding to the data bits.

When implemented in software, the elements of the invention are essentially the code segments to perform the necessary tasks. The code segments can be stored in a processor readable medium or transmitted by a computer data signal. The “processor readable medium” may include any medium that can store or transfer information. Examples of the processor readable medium include an electronic circuit, a semiconductor memory device, a ROM, a flash memory or other non-volatile memory, a floppy diskette, a CD-ROM, an optical disk, a hard disk, a fiber optic medium, a radio frequency (RF) link, etc.

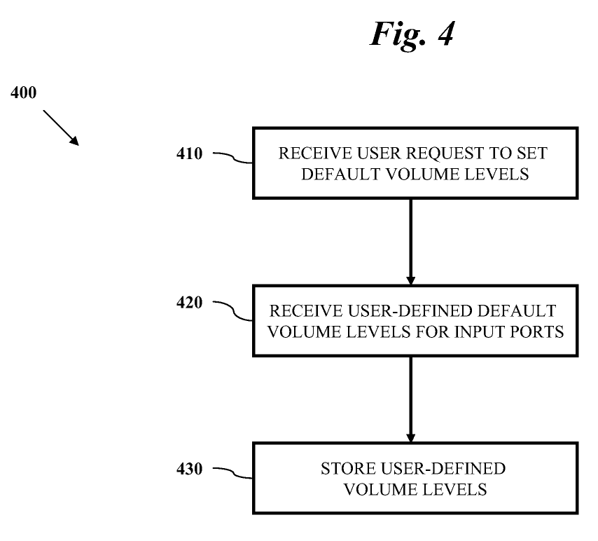

Referring to FIG. 4, a process 400 is depicted for implementing one aspect of the invention according to one embodiment. In particular, process 400 begins at block 410 where a user request to set default volume levels may be received by a user electronic device (e.g., electronic device 105) from a user input device (e.g., user input device 110). While in one embodiment, process 400 may be implemented by a television, it should equally be appreciated that other types of electronic devices may similarly implement one or more aspects of the invention.

The operation of block 410 may comprise receiving a user request to access a settings menu of the electronic device in question. For example, many televisions have a sound or audio settings submenu which may be accessible from a device main menu. It should be appreciated that numerous and varied menu configurations and options would all be consistent with the principles of the invention. It should be appreciated that such a request may be processed by the electric user device's processing logic, such as processing logic 115.

Process 400 continues to block 420 where specific user-defined default volume levels may be received, again from any user input device via any settings menu of the electronic device, for example. Again, this user-provided information may be processed by the electric user device's processing logic.

In certain embodiments, the user-defined default volume levels will correspond to the individual external input ports of the electronic device, such as PC Input, Video 1, Video 2, HDMI 1, HDMI 2, digital music (DM) Input, etc. Obviously the number and name of the individual input ports may vary from device to device.

By way of providing a non-limiting example of the operation of block 220, a user may, for example, key-in (e.g., using a remote control or similar input device) a volume setting of 9 for the HDMI 1 port, while then keying-in a volume setting of 49 for the PC Input port. Since HDMI requires a much lower volume setting than a PC Input would, this would enable the user to experience a consistent and even volume level, even when switching between external inputs.

Additionally, the user-defined default volume level may be based on a relative discrepancy between the actual volume experienced for one external input port as compared to the actual volume that is expected to be experienced for some other external input port. That is, rather than providing a numerical input, the user may provide a volume adjustment (e.g., increase by X, decrease by X) for one or more input pairs (e.g., going from Video 1 to HDMI; going from DM input to Video 2, etc.).

Similarly, the user may wish for his/her music volume level to be different than the default television listening level. When the user's music source is connected to a particular input port (e.g., DM input port), setting the default volume level for the DM input port higher than the other ports would achieve the desired result of being able to listen to music at a consistently elevated level, without the need to manually adjust the volume setting and irrespective of how high or low the volume setting was prior to when the user switched to the DM input port. Thus, the user-defined default volume levels may be provided as a function of the type of media source associated with the external input port in question. That is, rather than providing a numerical input, the user may provide a media type (e.g., music, movies, etc.) which can then be used to set the default volume level for a given input port.

Continuing to refer to FIG. 4, process 400 may then continue to block 530 where any user-defined default volume levels received above at block 420 may be stored by the electronic user device (e.g., memory 135). In certain embodiments, the user-defined default volume levels to be stored at block 420 may be stored in the same manner and location as other user-provided audio/video settings.

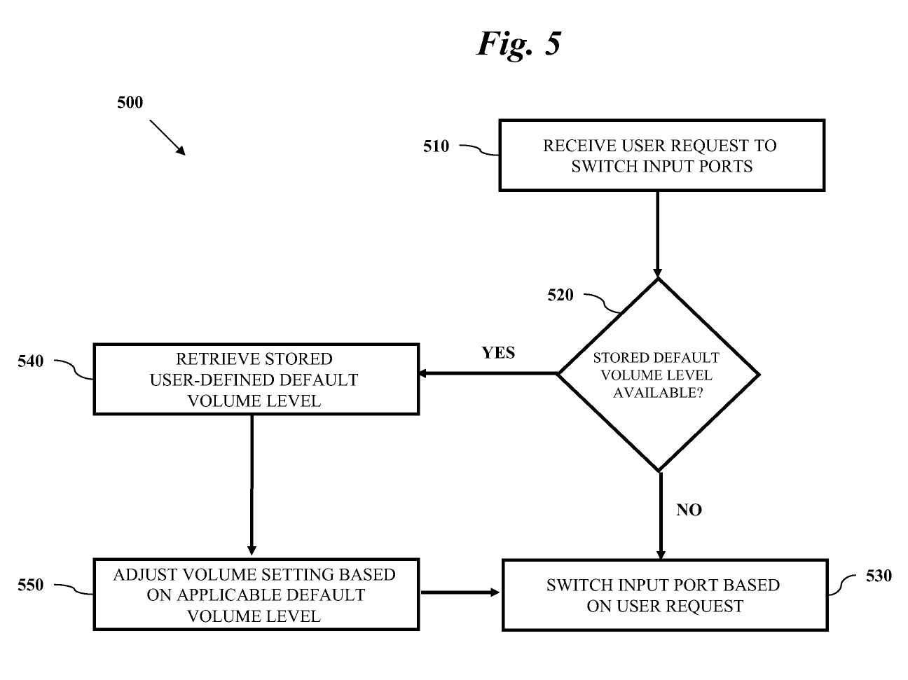

Referring now to FIG. 5, a process 500 is depicted for implementing another aspect of the invention according to one embodiment. It should be appreciated that, as with process 400 above, process 500 may be implemented by a television, or similarly any other type of electronic device. Process 500 begins at block 510 where a user request to switch from one input port to another is received. In particular, the user request may correspond to switching an active external input port of the electronic user device to a new external input. In one embodiment, this user request may be received by a user electronic device (e.g., electronic device 105) from a user input device (e.g., user input device 110). Once received, this request may be processed by the electric user device's processing logic, such as processing logic 115.

Process 500 continues to block 520 where a determination may be made as to whether there is a stored user-defined default volume level that corresponds to the user requested input port. If not, process 500 may continue to block 530 where the user electronic device may simply switch the current active external input port to the requested input port in accordance with the user request of block 510 without any adjustment of the volume level taking place. However, if it is determined at block 520 that there is a stored user-defined default volume level corresponding to the requested input port, then process 500 may continue to block 540 where the previously-stored user-defined default volume level corresponding to the selected port may be retrieved. While in one embodiment, the electronic user device's processing logic (e.g., processing logic 115) may retrieve the desired default volume level from a local memory (e.g., memory 135), it should be appreciated that numerous other configurations for retrieving such stored default volume level information may be used in accordance with the principles of the invention.

Once the proper volume level information has been retrieved at block 540, process 500 may then continue to block 550 where the current volume setting of the electronic user device may be adjusted based on the retrieved applicable default volume level information. The adjustment operation of block 550 may involve comparing a current volume setting to the retrieved volume level and determining if the current volume setting needs to be raised, lowered or left the same.

Once the volume level has been adjusted at block 550, process 500 may then continue to block 530 where the user electronic device may switch the active external input port to the new external input port in accordance with the user request of block 510.

While process 500 depicts the adjustment operation of block 550 as occurring before the port switching operation of 530, it should be appreciated that the port switching of block 530 may alternatively occur just before the volume adjusting operation of block 550, or simultaneously therewith.

In this fashion, a user may switch between external input ports (and hence media content sources) while not experiencing the volume level increases and decreases that currently exist when switching from certain input types to other input types. Additionally, users are now able to customize the volume level for their various media sources, such as having a higher volume level for music when switching the input port connected to a music source (e.g., DM input port), or a lower volume level when switching to the input port connected to standard television broadcast content. In short, user may also now customize the initial volume setting on an input-port-specific basis.

While certain exemplary embodiments have been described and shown in the accompanying drawings, it is to be understood that such embodiments are merely illustrative of and not restrictive on the broad invention, and that this invention not be limited to the specific constructions and arrangements shown and described, since various other modifications may occur to those ordinarily skilled in the art. Trademarks and copyrights referred to herein are the property of their respective owners.

What is claimed is:

1. A method for providing volume control for an electronic user device comprising:
receiving a user request to switch an active external input port of the electronic user device to a new external input port;
determining if a user-defined default volume level is available for the new external input port;
retrieving the user-defined default volume level corresponding to the new external input port;
adjusting a current volume setting based on said retrieved user-defined default volume level; and
switching the active external input port to the new external input port.

2. The method of claim 1, wherein the electronic user device comprises a television.

3. The method of claim 1, wherein retrieving the user-defined default volume level comprises retrieving the user-defined default volume level from a memory of the electronic user device.

4. The method of claim 1, wherein prior to receiving the user request to switch the active external input port, the method further comprises:
receiving a user request to set the user-defined default volume level;
receiving the user-defined default volume level; and
storing said user-defined default volume level is a memory of the electronic user device.

5. The method of claim 4, further comprising displaying a settings menu in response to the receiving the user request to set the user-defined default volume level.

6. The method of claim 1, wherein retrieving the user-defined default volume level comprises selecting the user-defined default volume level corresponding to the new external input port from among a plurality of user-defined default volume levels corresponding to a plurality of external input ports of the electronic device.

7. The method of claim 1, wherein adjusting the current volume setting comprises:
comparing the current volume setting to the retrieved user-defined default volume level;
reducing the current volume setting when the current volume setting is greater than the retrieved user-defined default volume level; and
increasing the current volume setting when the current volume setting is less than the retrieved user-defined default volume level.

8. The method of claim 1, wherein switching the active external input port is performed prior to said adjusting the current volume level.

9. The method of claim 1, wherein the user-defined default volume level is based on a relative discrepancy between an actual volume for the active external input port and an expected volume for the new external input port.

10. The method of claim 1, wherein the user-defined default volume level is based on a type of media source associated with the new external input port.

11. A user electronic device comprising:
a device input interface having a plurality of external input ports for connection to external media source devices;
a user input interface configured to receive user inputs; and
a processor coupled to the device input interface and the user input interface, the processor configured to:
receive a user request via the user input interface to switch an active external input port of the device input interface to a new external input port,
determine if a user-defined default volume level is available for the new external input port,
retrieve the user-defined default volume level corresponding to the new external input port,
adjust a current volume setting based on said retrieved user-defined default volume level, and
switch the active external input port of the device input interface to the new external input port.

12. The user electronic device of claim 11, wherein the electronic user device comprises a television.

13. The user electronic device of claim 11, wherein the processor is configured to retrieve the user-defined default volume level from a memory of the electronic user device.

14. The user electronic device of claim 11, wherein prior to receiving the user request to switch the active external input port, the processor is further configured to:
receive a user request via the user input interface to set the user-defined default volume level,
receive the user-defined default volume level via the user input interface, and
store said user-defined default volume level is a memory of the electronic user device.

15. The user electronic device of claim 14, wherein the processor is further configured to display a settings menu in response to the receiving the user request to set the user-defined default volume level.

16. The user electronic device of claim 11, wherein the processor is further configured to select the user-defined default volume level corresponding to the new external input port from among a plurality of user-defined default volume levels corresponding to a plurality of external input ports of the electronic device.

17. The user electronic device of claim 11, wherein the processor, in order to adjust the current volume setting, is further configured to:
compare the current volume setting to the retrieved user-defined default volume level,
reduce the current volume setting when the current volume setting is greater than the retrieved user-defined default volume level, and
increase the current volume setting when the current volume setting is less than the retrieved user-defined default volume level.

18. The user electronic device of claim 11, wherein the processor is further configured to switch the active external input port prior to adjusting the current volume level.

19. The user electronic device of claim 11, wherein the user-defined default volume level is based on a relative discrepancy between an actual volume for the active external input port and an expected volume for the new external input port.

20. The user electronic device of claim 11, wherein the user-defined default volume level is based on a type of media source associated with the new external input port.
